(19) United States
(12) Patent Application Publication
(10) Pub. No.: US 2016/0260832 A1
(43) Pub. Date: Sep. 8, 2016

(54) SEMICONDUCTOR DEVICE, METHOD OF MANUFACTURING THE SAME AND POWER CONVERTER

(71) Applicant: TOYODA GOSEI CO., LTD., Kiyosu-shi (JP)

(72) Inventors: Tohru OKA, Kiyosu-shi (JP); Tsutomu INA, Kiyosu-shi (JP)

(21) Appl. No.: 15/059,195

(22) Filed: Mar. 2, 2016

(30) Foreign Application Priority Data
Mar. 6, 2015 (JP) 2015-044212

(51) Int. Cl. H01L 29/78; H01L 29/16; H02M 7/04; H01L 29/26; H01L 29/40; H01L 29/423; H01L 29/20

(52) U.S. Cl. CPC H01L 29/7813; H01L 29/42368; H01L 29/1608; H01L 29/1602; H01L 29/2003; H01L 29/26; H01L 29/401; H02M 7/04

(57) ABSTRACT

An object is to effectively reduce electric field crowding in a trench MIS structure in a semiconductor device. The semiconductor device comprises a first semiconductor layer; a second semiconductor layer; a third semiconductor layer; a trench that is configured to include a side face and a bottom face; a first insulator that is mainly made of a first insulating material, is provided as a film formed from the side face over the bottom face and is configured to include a side face film portion and a bottom face film portion; a second insulator that is mainly made of a second insulating material having a higher relative permittivity than relative permittivity of the first insulating material and is formed in at least a corner portion of an area defined by the side face film portion and the bottom face film portion; and an electrode that is formed inside of the trench via the first insulator and the second insulator. A thickness Th1 of the second insulator in an area located in the corner portion, relative to a surface of the bottom face film portion is greater than a thickness Th2 of the second insulator in an area where the side face film portion is placed between the second insulator and the second semiconductor layer, relative to a surface of the side face film portion.

### CROSS REFERENCE TO RELATED APPLICATION

The present application claims the priority based on Japanese Patent Application No. 2015-44212 filed on Mar. 6, 2015, the disclosures of which are hereby incorporated by reference in its entirety.

### BACKGROUND

1. Technical Field

The present invention relates to a semiconductor device, a method of manufacturing the same and a power converter

2. Description of the Related Art

A trench MIS (metal-insulator-semiconductor) structure in which an electrode is provided via an insulator in a trench (groove) formed in a semiconductor layer has been known as the structure of a semiconductor device (semiconductor element). JP 2012-216675A, JP H04-188877A and JP 2013-122953A disclose techniques with regard to the trench MIS structure with a view to reducing the electric field crowding at an end of an interface between a semiconductor and an insulator on a bottom face of a trench.

JP 2012-216675A discloses the technique with regard to the trench MIS structure that makes the thickness of an insulator formed on a bottom face of a trench greater than the thickness of an insulator formed on a side face of the trench.

JP H04-188877A discloses the technique with regard to the trench MIS structure that forms an oxide film (insulator) on at least a side face of a trench and forms a film (insulator) having a higher relative permittivity than the relative permittivity of the oxide film on a bottom face of the trench.

JP 2013-122953A discloses the technique with regard to the trench MIS structure that forms a first insulating film on a bottom face of a trench, forms a second insulating film on the first insulating film and on a side face of the trench and additionally forms a third insulating film having a higher relative permittivity on the second insulating film.

In the trench MIS structure, the inventors have found that electric field crowding is more likely to occur in a corner portion of an interface between an electrode and an insulator rather than at an end of an interface between a semiconductor and an insulator in the bottom face of the trench. Any of the techniques disclosed in JP 2012-216675A, JP H04-188877A and JP 2013-122953A does not effectively reduce the electric field crowding in the trench MIS structure. In the technique of JP H04-188877A, when only an insulator having the high relative permittivity is formed on the bottom face of the trench, this makes breakdown more likely to occur in the semiconductor layer even when breakdown in the insulator is avoided.

By taking into account the foregoing, there is a need for a technique that effectively reduces the electric field crowding in the trench MIS structure in the semiconductor device. Other needs with regard to the semiconductor drive include cost reduction, miniaturization, easy manufacture, resource saving, improvement of usability and improvement of durability.

### SUMMARY

In order to solve at least part of the problems described above, the invention may be implemented by aspects described below.

(1) According to one aspect of the invention, there is provided a semiconductor device. The semiconductor device of this aspect comprises: a first semiconductor layer that is configured to have one characteristic out of n-type and p-type characteristics; a second semiconductor layer that is configured to have the other characteristic out of the n-type and p-type characteristics that is different from the one characteristic, and is stacked on the first semiconductor layer; a third semiconductor layer that is configured to have the one characteristic and is stacked on the second semiconductor layer; a trench that is formed from the third semiconductor layer to penetrate through the second semiconductor layer and to be recessed into the first semiconductor layer and is configured to include a side face and a bottom face; a first insulator that is mainly made of a first insulating material, is provided as a film formed from the side face over the bottom face, and is configured to include a side face film portion formed on the side face and a bottom face film portion formed on the bottom face; a second insulator that is mainly made of a second insulating material having a higher relative permittivity than relative permittivity of the first insulating material and is formed in at least a corner portion of an area defined by the side face film portion and the bottom face film portion; and an electrode that is formed inside of the trench via the first insulator and the second insulator, wherein a thickness Th1 of the second insulator in an area located in the corner portion is greater than a thickness Th2 of the second insulator in an area where the side face film portion is placed between the second insulator and the second semiconductor layer, wherein the thickness Th1 denotes a thickness relative to a surface of the bottom face film portion and the thickness Th2 denotes a thickness relative to a surface of the side face film portion. The semiconductor device of this aspect enables the second insulator located in the corner portion to effectively reduce the electric field crowding at an interface of the electrode. This configuration can thus effectively reduce the electric field crowding in the trench MIS structure.

(2) In the semiconductor device of the above aspect, the thickness Th1 may be greater than a thickness of the first insulator. This configuration more effectively reduces the electric field crowding at an interface with the electrode.

(3) In the semiconductor device of the above aspect, the bottom face film portion may have a thickness that is equal to or greater than a thickness of the side face film portion. This configuration enables the bottom face film portion of the first insulator to effectively reduce the electric field crowding at an interface of the first semiconductor layer in the bottom face of the trench.

(4) In the semiconductor device of the above aspect, the thickness Th1 may be equal to or greater than twice a thickness of the bottom face film portion. This configuration further effectively reduces the electric field crowding at an interface with the electrode.

(5) In the semiconductor device of the above aspect, an interface between the second insulator and the electrode may be located on a third semiconductor layer side of an interface between the first semiconductor layer and the second semiconductor layer. This configuration reduces the depth of the trench and gains the thickness of the first semiconductor layer. This results in enhancing the breakdown voltage of the semiconductor layer.

(6) In the semiconductor device of the above aspect, the second insulator may be a film formed from the side face film portion over the bottom face film portion. This configuration enables the second insulator to be readily provided by a film formation technique having anisotropy.

(7) In the semiconductor device of the above aspect, the second insulator may include a film portion that is formed on the side face film portion to have the thickness Th2; and a film portion that is formed on the bottom face film portion to have the thickness Th1. This configuration enables the second insulator to be readily provided by a film formation technique having anisotropy.

(8) In the semiconductor device of the above aspect, the second insulator may be formed partly thicker in the corner portion. This configuration reduces the amount of the second insulating material used.

(9) In the semiconductor device of the above aspect, the second insulator may be partly formed in the corner portion. This configuration reduces the amount of the second insulating material used.

(10) In the semiconductor device of the above aspect, the first insulating material may include at least one selected from the group consisting of silicon dioxide (SiO₂), silicon oxynitride (SiON), aluminum oxide (Al₂O₃), aluminum oxynitride (AlON) and gallium oxide (Ga₂O₃). This configuration enables the first insulator to be readily provided.

(11) In the semiconductor device of the above aspect, the second insulating material may include at least one of oxides and oxynitrides containing at least one element selected from the group consisting of aluminum (Al), hafnium (Hf), titanium (Ti), zirconium (Zr), tantalum (Ta) and lanthanum (La). This configuration enables the second insulator to be readily provided.

(12) In the semiconductor device of the above aspect, at least one semiconductor layer among the first semiconductor layer, the second semiconductor layer and the third semiconductor layer may be mainly made of a semiconductor that has a greater band gap than a band gap of silicon (Si). This configuration effectively reduces the electric field crowding in the trench MIS structure in a semiconductor device that requires a higher breakdown voltage than that of the semiconductor using silicon (Si).

(13) In the semiconductor device of the above aspect, at least one semiconductor layer among the first semiconductor layer, the second semiconductor layer and the third semiconductor layer may be mainly made of at least one selected from the group consisting of silicon carbide (SiC), a nitride semiconductor, diamond and gallium oxide (Ga₂O₃). This configuration effectively reduces the electric field crowding in the trench MIS structure in a semiconductor device that requires a higher breakdown voltage than that of the semiconductor using silicon (Si).

(14) According to another aspect of the invention, there is provided a power converter comprising the semiconductor device of any of the above aspects. This configuration enhances the power conversion efficiency.

(15) According to another aspect of the invention, there is provided a method of manufacturing a semiconductor device. The method comprises forming a first semiconductor layer having one characteristic out of n-type and p -type characteristics, on a substrate; stacking a second semiconductor layer having the other characteristic out of the n-type and p-type characteristics that is different from the one characteristic, on the first semiconductor layer; stacking a third semiconductor layer having the one characteristic, on the second semiconductor layer; forming a trench that includes a side face and a bottom face by etching from the third semiconductor layer through the second semiconductor layer to the first semiconductor layer; forming a first insulator as a film formed from the side face over the bottom face by using a first insulating material, such that the first insulator includes a side face film portion formed on the side face and a bottom face film portion formed on the bottom face; forming a second insulator in at least a corner portion of an area defined by the side face film portion and the bottom face film portion by using a second insulating material having a higher relatively permittivity than relative permittivity of the first insulating material; and forming an electrode inside of the trench that the first insulator and the second insulator are formed in, wherein the forming the second insulator comprises making a thickness Th1 of the second insulator in an area located in the corner portion greater than a thickness Th2 of the second insulator in an area where the side face film portion is placed between the second insulator and the second semiconductor layer, wherein the thickness Th1 denotes a thickness relative to a surface of the bottom face film portion and the thickness Th2 denotes a thickness relative to a surface of the side face film portion. The manufacturing method of this aspect enables the second insulator located in the corner portion to effectively reduce the electric field crowding at an interface of the electrode. This configuration can thus effectively reduce the electric field crowding in the trench MIS structure.

(16) In the method of manufacturing the semiconductor device of the above aspect, the forming the second insulator may comprise forming the second insulator by sputtering. The manufacturing method of this aspect enables the second insulator to be readily formed.

(17) In the method of manufacturing the semiconductor device of the above aspect, the sputtering may be electron cyclotron resonance sputtering. The manufacturing method of this aspect enables the second insulator to be readily formed.

(18) The method of manufacturing the semiconductor device of the above aspect may further comprise adjusting thickness of the second insulator by controlling an angle between a radiation direction of target particles and the substrate. The manufacturing method of this aspect enables the second insulator to be readily formed.

The invention may be implemented by any of various aspects other than the semiconductor device, the method of manufacturing the semiconductor device and the power converter described above. For example, the invention may be implemented by electric equipment in which the semiconductor device of any of the above aspects is incorporated and a manufacturing apparatus for manufacturing the semiconductor device.

According to the above aspects of the invention, the second insulator located in the corner portion effectively reduces the electric field crowding at an interface of the electrode. This configuration can thus effectively reduce the electric field crowding in the trench MIS structure.

### BRIEF DESCRIPTION OF DRAWINGS

FIG. 1 is a diagram illustrating the configuration of a power converter 10;

FIG. 2 is a sectional view schematically illustrating the configuration of the semiconductor device according to a first embodiment;

FIG. 3 is a sectional view schematically illustrating the detailed configuration of the semiconductor device according to the first embodiment;

FIG. 4 is a process chart showing a method of manufacturing the semiconductor device according to the first embodiment;

FIG. 5 is a graph showing the results of an evaluation test with regard to the breakdown voltage;

FIG. 6 is a sectional view schematically illustrating the configuration of a semiconductor device according to a second embodiment;

FIG. 7 is a sectional view schematically illustrating the configuration of a semiconductor device according to a third embodiment;

FIG. 8 is a sectional view schematically illustrating the configuration of a semiconductor device according to a fourth embodiment;

FIG. 9 is a sectional view schematically illustrating the configuration of a semiconductor device according to a fifth embodiment; and

FIG. 10 is a sectional view schematically illustrating the configuration of a semiconductor device according to a sixth embodiment.

### DESCRIPTION OF EMBODIMENTS

### A. First Embodiment

A-1. Configuration of Power Converter

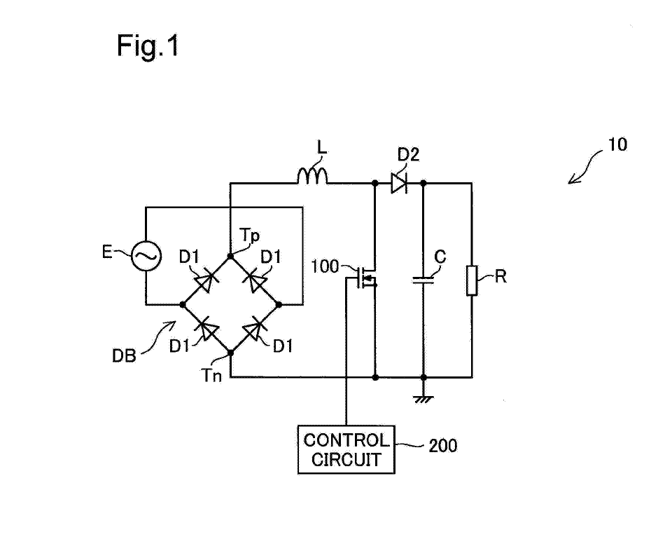

FIG. 1 is a diagram illustrating the configuration of a power converter 10. The power converter 10 is an apparatus configured to convert electric power supplied from an AC power source E to a load R. The power converter 10 includes a semiconductor device 100, a control circuit 200, four diodes D1, a coil L, a diode D2 and a capacitor C as components of a power factor correction circuit configured to improve the power factor of the AC power source E.

In the power converter 10, the four diodes D1 constitute a diode bridge DB configured to rectify the AC voltage of the AC power source E. The diode bridge DB has a positive electrode output terminal Tp and a negative electrode output terminal Tn as DC-side terminals. The coil L is connected with the positive electrode output terminal Tp of the diode bridge DB. The anode side of the diode D2 is connected with the positive electrode output terminal Tp via the coil L. The cathode side of the diode D2 is connected with the negative electrode output terminal Tn via the capacitor C. The load R is connected in parallel with the capacitor C.

The semiconductor device 100 of the power converter 10 is an FET (field effect transistor). The source side of the semiconductor device 100 is connected with the negative electrode output terminal Tn. The drain side of the semiconductor device 100 is connected with the positive electrode output terminal Tp via the coil L. The gate side of the semiconductor device 100 is connected with the control circuit 200. The control circuit 200 of the power converter 10 controls the electric current between the source and the drain of the semiconductor device 100, based on the voltage output to the load R and the electric current flowing in the diode bridge DB, in order to improve the power factor of the AC power source E.

A-2. Configuration of Semiconductor Device

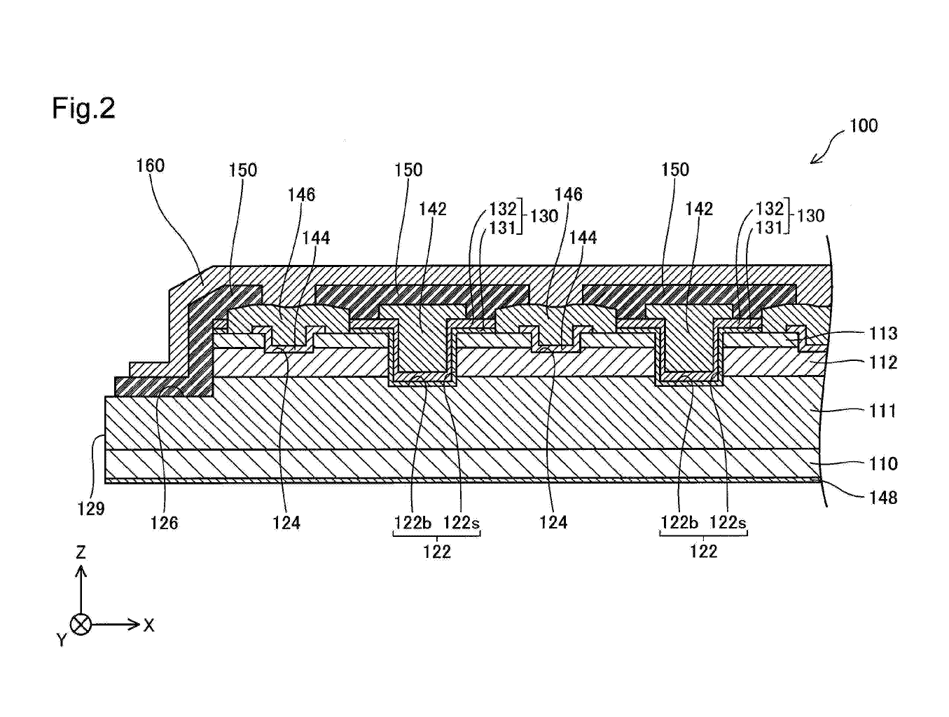

FIG. 2 is a sectional view schematically illustrating the configuration of the semiconductor device 100 according to a first embodiment. XYZ axes orthogonal to one another are illustrated in FIG. 2. Among the XYZ axes of FIG. 2, the X axis denotes a left-right axis on the sheet surface of FIG. 2. +X-axis direction denotes a rightward direction on the sheet surface, and −X-axis direction denotes a leftward direction on the sheet surface. Among the XYZ axes of FIG. 2, the Y axis denotes a front-back axis on the sheet surface of FIG. 2. +Y-axis direction denotes a backward direction on the sheet surface, and −Y-axis direction denotes a forward direction on the sheet surface. Among the XYZ axes of FIG. 2, the Z axis denotes a top-bottom axis on the sheet surface of FIG. 2. +Z-axis direction denotes an upward direction on the sheet surface, and −Z-axis direction denotes a downward direction on the sheet surface. The XYZ axes illustrated in other drawings correspond to the XYZ axes of FIG. 2.

According to this embodiment, the semiconductor device 100 is a GaN-based semiconductor device formed using gallium nitride (GaN). According to this embodiment, the semiconductor device 100 is a vertical trench MOSFET (metal-oxide-semiconductor field effect transistor). According to this embodiment, the semiconductor device 100 is used for power control and is also called power device.

The semiconductor device 100 includes a substrate 110, a semiconductor layer 111, a semiconductor layer 112 and a semiconductor layer 113. The semiconductor device 100 includes trenches 122, recesses 124, a step 126 and a terminating portion 129 as structures formed in these semiconductor layers. The semiconductor device 100 also includes an insulating film 130, gate electrodes 142, body electrodes 144, source electrodes 146 and a drain electrode 148. According to this embodiment, the semiconductor device 100 further includes an insulating film 150 and a wiring electrode 160.

The substrate 110 of the semiconductor device 100 is a plate-like semiconductor extended along the X axis and the Y axis. According to this embodiment, the substrate 110 is mainly made of gallium nitride (GaN). In the description hereof, the expression of “mainly made of gallium nitride (GaN)” means containing gallium nitride (GaN) at 90% or a higher molar fraction. According to this embodiment, the substrate 110 is an n-type semiconductor containing silicon (Si) as the donor element. According to this embodiment, the average concentration of silicon (Si) contained in the substrate 110 is about 1×10¹⁸ cm⁻³.

The semiconductor layer 111 of the semiconductor device 100 is a first semiconductor layer that is located on the +Z-axis direction side of the substrate 110 and is extended along the X axis and the Y axis. According to this embodiment, the semiconductor layer 111 is mainly made of gallium nitride (GaN). According to this embodiment, the semiconductor layer 111 is an n-type semiconductor having n-type characteristics. According to this embodiment, the semiconductor layer 111 contains silicon (Si) as the donor element. According to this embodiment, the average concentration of silicon (Si) contained in the semiconductor layer 111 is about 1×10¹⁶ cm⁻³. According to this embodiment, the thickness (length in the Z-axis direction) of the semiconductor layer 111 is about 10 μm (micrometers).

The semiconductor layer 112 of the semiconductor device 100 is a second semiconductor layer that is located on the +Z-axis direction side of the semiconductor layer 111 and is extended along the X axis and the Y axis. According to this embodiment, the semiconductor layer 112 is mainly made of gallium nitride (GaN). According to this embodiment, the semiconductor layer 112 is a p-type semiconductor having p-type characteristics. According to this embodiment, the semiconductor layer 112 contains magnesium (Mg) as the acceptor element. According to this embodiment, the average concentration of magnesium (Mg) contained in the semiconductor layer 112 is about 4×10¹⁸ cm⁻³. According to this embodiment, the thickness (length in the Z-axis direction) of the semiconductor layer 112 is about 1.0 μm.

The semiconductor layer 113 of the semiconductor device 100 is a third semiconductor layer that is located on the +Z-axis direction side of the semiconductor layer 112 and is extended along the X axis and the Y axis. According to this embodiment, the semiconductor layer 113 is mainly made of gallium nitride (GaN). According to this embodiment, the semiconductor layer 113 is an n-type semiconductor having n-type characteristics. According to this embodiment, the semiconductor layer 113 contains silicon (Si) as the donor element. According to this embodiment, the average concentration of silicon (Si) contained in the semiconductor layer 113 is about 3×10¹⁸ cm⁻³. According to this embodiment, the thickness (length in the Z-axis direction) of the semiconductor layer 113 is about 0.2 μm.

The trench 122 of the semiconductor device 100 is a groove that is formed from the +Z-axis direction side of the semiconductor layer 113 to penetrate through the semiconductor layer 112 and to be recessed into the semiconductor layer 111. According to this embodiment, the trench 122 is a structure formed by dry etching of the semiconductor layers 111, 112 and 113. The trench 122 has a side face 122s and a bottom face 122b. The side face 122s of the trench 122 denotes a surface extended in the Z-axis direction, out of the surfaces defining the trench 122. The bottom face 122b of the trench 122 denotes a surface arranged to face the +Z-axis direction and extended in the X-axis direction and in the Y-axis direction, out of the surfaces defining the trench 122.

The recess 124 of the semiconductor device 100 is a concave that is recessed from the +Z-axis direction side of the semiconductor layer 113 into the semiconductor layer 112. According to this embodiment, the recess 124 is a structure formed by dry etching of the semiconductor layers 112 and 113.

The step 126 of the semiconductor device 100 is a region that is formed from the +Z-axis direction side of the semiconductor layer 113 to penetrate through the semiconductor layer 112 and to be recessed into the semiconductor layer 111. According to this embodiment, the step 126 is formed by dry etching of the semiconductor layers 111, 112 and 113. The terminating portion 129 of the semiconductor device 100 is a region that is adjacent to the step 126 and defines termination of the semiconductor layers 111, 112 and 113. According to this embodiment, the terminating portion 129 is a structure formed by dicing.

The insulating film 130 of the semiconductor device 100 is a film having electrical insulating properties. According to this embodiment, the insulating film 130 is formed from inside to outside of the trench 122. According to another embodiment, the insulating film 130 may be formed only inside of the trench 122. According to this embodiment, the insulating film 130 includes an insulating film 131 and an insulating film 132.

The insulating film 131 of the insulating film 130 is a first insulator that is mainly made of silicon dioxide (SiO₂) as first insulating material. The insulating film 131 is a film formed from the side face 122s over the bottom face 122b inside of the trench 122. According to this embodiment, the insulating film 131 is formed from inside of the trench 122 to a +Z-axis direction side surface of the semiconductor layer 113 outside of the trench 122. The details of the insulating film 131 will be described later.

The insulating film 132 of the insulating film 130 is a second insulator that is mainly made of zirconium oxynitride (ZrON) as second insulating material having a higher relative permittivity than that of the first insulating material. According to this embodiment, the insulating film 132 is a film stacked over the entire area of the insulating film 131. The details of the insulating film 132 will be described later.

The gate electrode 142 of the semiconductor device 100 is an electrode that is formed inside of the trench 122 across the insulating film 130. According to this embodiment, the gate electrode 142 is formed from inside to outside of the trench 122. According to this embodiment, the gate electrode 142 is mainly made of aluminum (Al). When a voltage is applied to the gate electrode 142, an inversion layer is formed in the semiconductor layer 112 to serve as a channel, and a conductive path is formed between the source electrode 146 and the drain electrode 148.

The body electrode 144 of the semiconductor device 100 is an electrode that is formed in the recess 124 and is in ohmic contact with the semiconductor layer 112. According to this embodiment, the body electrode 144 is an electrode obtained by stacking a layer mainly made of palladium (Pd) and processing the stacked layer by heat treatment.

The source electrode 146 of the semiconductor device 100 is an electrode that is in ohmic contact with the semiconductor layer 113. According to this embodiment, the source electrode 146 is formed on the body electrode 144 toward the +Z-axis direction side surface of the semiconductor layer 113. According to another embodiment, the source electrode 146 may be formed in a region away from the body electrode 144. According to this embodiment, the source electrode 146 is an electrode obtained by stacking a layer mainly made of aluminum (Al) on a layer mainly made of titanium (Ti) and processing the stacked layers by heat treatment.

The drain electrode 148 of the semiconductor device 100 is an electrode that is in ohmic contact with a −Z-axis direction side surface of the substrate 110. According to this embodiment, the drain electrode 148 is an electrode obtained by stacking a layer mainly made of aluminum (Al) on a layer mainly made of titanium (Ti) and processing the stacked layers by heat treatment.

According to this embodiment, the semiconductor device 100 includes a plurality of trench structures including the insulating film 130 and the gate electrodes 142 formed in the trenches 122, and a plurality of recess structures including the body electrodes 144 and the source electrodes 146 formed in the recesses 124. According to this embodiment, the trench structures and the recess structures are arranged alternately in the X-axis direction. According to this embodiment, the trench structures and the recess structures are extended in the Y-axis direction. According to this embodiment, the plurality of gate electrodes 142 are connected in parallel in the plane of the semiconductor device 100. According to this embodiment, the plurality of source electrodes 146 are connected in parallel via the wiring electrode 160.

The insulating film 150 of the semiconductor device 100 is disposed to cover the step 126, the insulating film 130, the gate electrodes 142 and the source electrodes 146. According to this embodiment, the insulating film 150 is mainly made of silicon dioxide (SiO₂).

The wiring electrode 160 of the semiconductor device 100 is an electrode that is formed on the insulating film 150. The wiring electrode 160 has connecting portions that are arranged to penetrate through the insulating film 150 and to be connected with the respective source electrodes 146. According to this embodiment, the wiring electrode 160 is mainly made of aluminum (Al). According to this embodiment, the wiring electrode 160 and the insulating film 150 form a field plate structure in the step 126. This configuration reduces the electric field crowding at an end of a pn junction interface in the step 126.

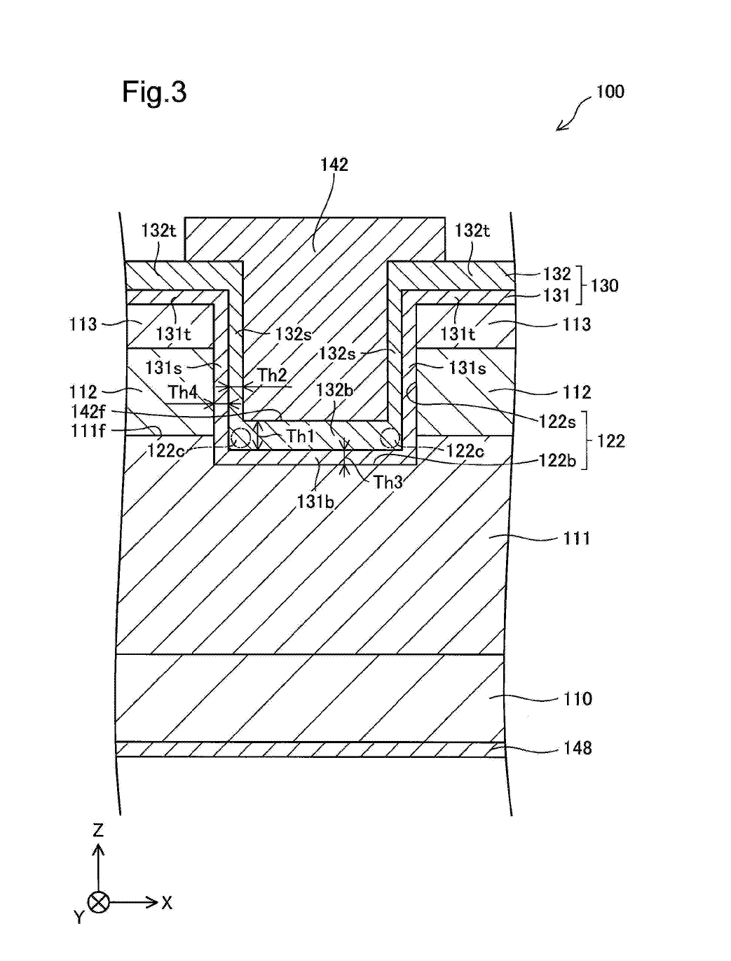

FIG. 3 is a sectional view schematically illustrating the detailed configuration of the semiconductor device 100 according to the first embodiment. FIG. 3 illustrates periphery of the trench 122 in a section of the semiconductor device 100.

The insulating film 131 of the insulating film 130 includes a side face film portion 131s, a bottom face film portion 131b and an upper film portion 131t. The side face film portion 131s of the insulating film 131 is a film portion formed on the side face 122s of the trench 122. The bottom face film portion 131b of the insulating film 131 is a film portion formed on the bottom face 122b of the trench 122. The upper film portion 131t of the insulating film 131 is a film portion formed on the +Z-axis direction side surface of the semiconductor layer 113.

The insulating film 132 of the insulating film 130 is formed in at least corner portions 122c. The corner portions 122c denote corners of an area defined by the side face film portion 131s and the bottom face film portion 131b of the insulating film 131. According to this embodiment, the insulating film 132 includes a side face film portion 132s, a bottom face film portion 132b and an upper film portion 132t. The side face film portion 132s of the insulating film 132 is a film portion formed on the side face film portion 131s of the insulating film 131. The bottom face film portion 132b of the insulating film 132 is a film portion formed on the bottom face film portion 131b of the insulating film 131. Part of the bottom face film portion 132b is located in the corner portions 122c. The upper film portion 132t of the insulating film 132 is a film portion formed on the upper film portion 131t of the insulating film 131.

A thickness Th1 shown in FIG. 3 denotes a thickness of the insulating film 132 in an area located at the corner portion 122c relative to the surface of the bottom face film portion 131b. A thickness Th2 shown in FIG. 3 denotes a thickness of the insulating film 132 in an area where the side face film portion 131s is placed between the insulating film 132 and the semiconductor layer 112 relative to the surface of the side face film portion 131s. The thickness Th1 is greater than the thickness Th2. In other words, the film thickness of the bottom face film portion 132b is greater than the film thickness of the side face film portion 132s. According to this embodiment, the thickness Th1 is 100 nm (nanometers), and the thickness Th2 is 30 nm.

In terms of ensuring the reliability on the breakdown voltage, a thickness Th3 of the bottom face film portion 131b is preferably equal to or greater than a thickness Th4 of the side face film portion 131s. According to this embodiment, the thickness Th3 of the bottom face film portion 131b is equal to the thickness Th4 of the side face film portion 131s. The smaller thickness Th4 of the side face film portion 131s is preferable in terms of the gate drive performance. In terms of ensuring the channel mobility, however, the thickness Th4 is preferably not smaller than 5 nm and is more preferably not smaller than 10 nm. According to this embodiment, the thickness Th3 is 50 nm, and the thickness Th4 is 50 nm.

In terms of reducing the electric field crowding at an interface 142f between the insulating film 132 and the gate electrode 142, the thickness Th1 of the insulating film 132 is preferably equal to or greater than the thicknesses Th3 and Th4 of the insulating film 131 and is more preferably equal to or greater than twice the thickness Th3.

According to this embodiment, the interface 142f between the insulating film 132 and the gate electrode 142 is located on the semiconductor layer 113-side (+Z-axis direction side) of a pn junction interface 111f between the semiconductor layer 111 and the semiconductor layer 112. In terms of reducing the on resistance, the position of the interface 142f is preferably on the −Z-axis direction side of a location which is away from the pn junction interface 111f by 0.1 μm in the +Z-axis direction.

In terms of reducing the electric field crowding at the pn junction interface 111f, the thickness Th3 of the insulating film 131 is preferably a thickness included in the −Z-axis direction side of the pn junction interface 111f.

A-3. Method of Manufacturing Semiconductor Device

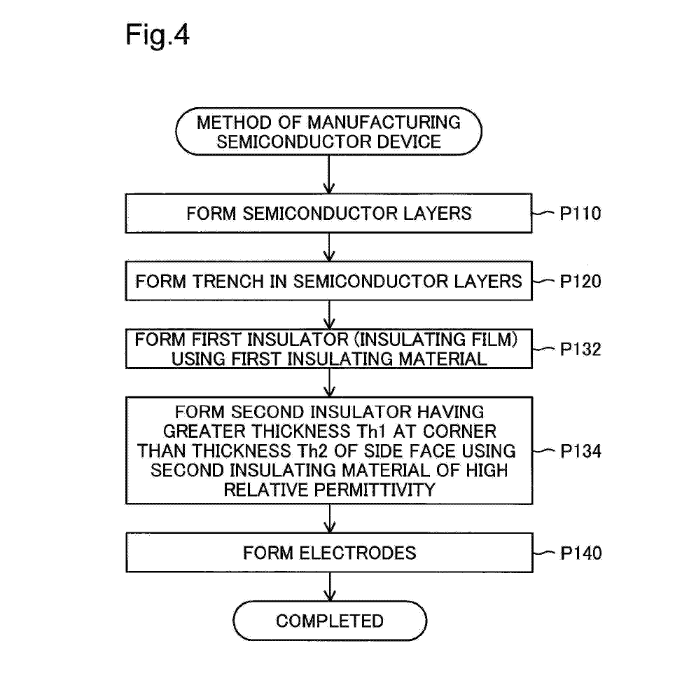

FIG. 4 is a process chart showing a method of manufacturing the semiconductor device 100 according to the first embodiment. The manufacturer first forms the semiconductor layers 111, 112 and 113 on the substrate 110 by crystal growth (process P110). According to this embodiment, the manufacturer forms the semiconductor layers 111, 112 and 113 by metal organic chemical vapor deposition (MOCVD).

After forming the semiconductor layers 111, 112 and 113, the manufacturer forms the trenches 122 by dry etching (process P120). According to this embodiment, the manufacturer forms the trenches 122 by dry etching using chlorine-based gases. According to this embodiment, the recesses 124 and the step 126 as well as the trenches 122 are formed by dry etching.

After forming the trenches 122, the manufacturer uses the first insulating material to form the insulating film 131 as the first insulator (process P132). According to this embodiment, the manufacturer uses silicon dioxide (SiO₂) as the first insulating material to form the insulating film 131. According to this embodiment, the manufacturer forms the insulating film 131 by atomic layer deposition (ALD). According to another embodiment, the manufacturer may form the insulating film 131 by sputtering or by plasma CVD. According to this embodiment, the manufacturer adjusts the film thicknesses Th3 and Th4 of the insulating film 131 to about 50 nm.

After forming the insulating film 131 (process P132), the manufacturer uses the second insulating material having the high relative permittivity to form the insulating film 132 (process P134). According to this embodiment, the manufacturer uses zirconium oxynitride (ZrON) as the second insulating material to form the insulating film 132. According to this embodiment, the manufacturer forms the insulating film 132 by electron cyclotron resonance sputtering (ECR sputtering). According to another embodiment, the manufacturer may form the insulating film 132 by magnetron sputtering or may form the insulating film 132 by atomic layer deposition (ALD).

According to this embodiment, the manufacturer forms the insulating film 132 by ECR sputtering using a target made of zirconium (Zr) in mixed gases of argon with nitrogen and oxygen. According to another embodiment, the manufacturer may use another inert gases (for example, xenon) in place of argon. According to this embodiment, in order to control the composition ratio of oxygen and nitrogen in the insulating film 132, the manufacturer controls the flow rate of argon gas in a range of 15 to 30 sccm, controls the flow rate of oxygen gas in a range of 0.1 to 3.0 sccm and controls the flow rate of nitrogen gas in a range of 4.3 to 17.0 sccm.

According to this embodiment, the manufacturer adjusts the thicknesses Th1 and Th2 of the insulating film 132 by controlling the angle between the radiation direction of the target particles and the substrate 110. According to this embodiment, the manufacturer adjusts the film thickness Th1 of the insulating film 132 in the Z-axis direction to about 100 nm and adjusts the film thickness Th2 of the insulating film 132 in the X-axis direction and in the Y-axis direction to about 30 nm.

In order to enhance the anisotropy of film formation, the angle between the radiation direction of the target particles and the substrate 110 is preferably between 45 degrees and 90 degrees, inclusive. The pressure of the mixed gases is preferably not lower than 0.07 Pa (Pascal) and not higher than 0.2 Pa and is more preferably not higher than 0.15 Pa. The lower RF power and the lower microwave power are preferable in terms of enhancing the anisotropy of film formation. In terms of ensuring the quality of film formation, however, the RF power and the microwave power are preferably between 50 W (watt) and 500 W, inclusive.

According to this embodiment, the manufacturer processes the insulating film 131 by heat treatment prior to film formation of the insulating film 132, and processes the insulating film 132 by heat treatment after film formation of the insulating film 132. According to another embodiment, the manufacturer may not process the insulating film 131 by heat treatment after film formation of the insulating film 131 but may collectively process the insulating film 131 and the insulating film 132 by heat treatment after film formation of the insulating film 132. According to this embodiment, the following conditions are employed for heat treatment of the insulating film 131 and the insulating film 132: atmosphere of heat treatment is nitrogen; temperature of heat treatment is 400° C.; and heat treatment time is 30 minutes. The atmosphere of heat treatment may be argon, hydrogen, mixed gases of hydrogen and nitrogen or vacuum. The temperature of heat treatment should be between 400° C. and 700° C., inclusive. The heat treatment time should be between 5 minutes and 90 minutes, inclusive.

After forming the insulating film 132 (process P134), the manufacturer forms the respective electrodes (process P140). According to this embodiment, the manufacturer forms the body electrodes 144, the source electrodes 146, the gate electrodes 142 and the drain electrode 148 in this sequence.

According to this embodiment, the manufacturer forms a layer mainly made of palladium (Pd) in the recess 124 by deposition to form the body electrode 144. According to this embodiment, the manufacturer sequentially stacks a layer mainly made of titanium (Ti) and a layer mainly made of aluminum (Al) on the body electrode 144 by deposition to form the source electrode 146. According to this embodiment, the manufacturer forms a layer mainly made of aluminum (Al) in the trench 122 by deposition to form the gate electrode 142. According to this embodiment, the manufacturer sequentially stacks a layer mainly made of titanium (Ti) and a layer mainly made of aluminum (Al) on the −Z-axis direction side surface of the substrate 110 by deposition to form the drain electrode 148.

According to this embodiment, the manufacturer processes each electrode by heat treatment after formation of the electrode. According to another embodiment, the manufacturer may collectively process two or more electrodes by heat treatment. The following conditions are employed for heat treatment of each electrode: atmosphere of heat treatment is nitrogen; temperature of heat treatment is 400° C.; and heat treatment time is 30 minutes.

After forming the respective electrodes (process P140), the manufacturer forms the insulating film 150 and the wiring electrode 160 to complete the semiconductor device 100.

A-4. Evaluation Test

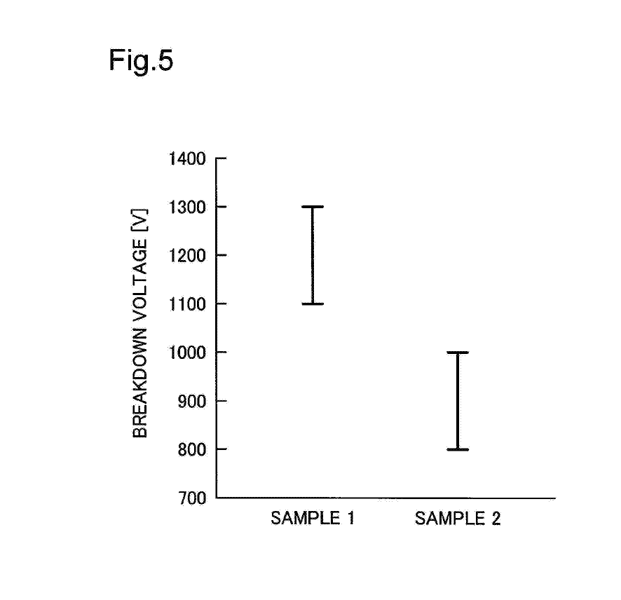

FIG. 5 is a graph showing the results of an evaluation test with regard to the breakdown voltage. In the evaluation test of FIG. 5, the examiner provided two semiconductor devices as samples 1 and 2 and evaluated the breakdown voltages of the respective samples.

The sample 1 was similar to the semiconductor device 100 except omission of the terminating structure of the field plate structure:

*film thicknesses of the insulating film 130 in the side face 122s of the trench 122:

film thickness Th4 of the insulating film 131 (silicon dioxide (SiO₂)): 50 nm;

film thickness Th2 of the insulating film 132 (zirconium oxynitride (ZrON)): 30 nm;

*film thicknesses of the insulating film 130 in the bottom face 122b of the trench 122:

film thickness Th3 of the insulating film 131 (silicon dioxide (SiO₂)): 50 nm; and

film thickness Th1 of the insulating film 132 (zirconium oxynitride (ZrON)): 100 nm.

The sample 2 was similar to the semiconductor device 100 except omission of the terminating structure of the field plate structure and inclusion of a single-layered insulating film in place of the insulating film 130. The insulating film in the trench 122 of the sample 2 was formed by atomic layer deposition (ALD) and was mainly made of silicon dioxide (SiO₂). The film thickness of the insulating film in the trench 122 of the sample 2 was 80 nm in both the side face 122s and the bottom face 122b of the trench 122.

Neither of the samples 1 and 2 have the terminating structure, so that the breakdown voltage of each sample is a voltage that causes breakdown at the gate electrode 142. As shown in FIG. 5, the breakdown voltage of the sample 1 is about 1100 to about 1300 V (volt), and the breakdown voltage of the sample 2 is about 800 to about 1000 V. This indicates that the breakdown voltage of the sample 1 is better than the breakdown voltage of the sample 2 by about 30%.

A-5. Advantageous Effects

According to the first embodiment described above, the thickness Th1 of the insulating film 132 formed on the insulating film 131 is greater than the thickness Th2. This configuration enables the insulating film 132 located in the corner portions 122c to effectively reduce the electric field crowding at the interface of the gate electrode 142. This configuration can thus effectively reduce the electric field crowding in the trench MIS structure formed in the trench 122.

The thickness Th1 of the insulating film 132 is greater than the thicknesses Th3 and Th4 of the insulating film 131. This configuration more effectively reduces the electric field crowding at the interface with the gate electrode 142.

The thickness Th3 of the bottom face film portion 131b is equal to or greater than the thickness Th4 of the side face film portion 131s. This configuration enables the bottom face film portion 131b of the insulating film 131 to effectively reduce the electric field crowding at the interface of the semiconductor layer 111 in the bottom face 122b of the trench 122.

The thickness Th1 of the insulating film 132 is equal to or greater than twice the thickness Th3 of the bottom face film portion 131b. This configuration more effectively reduces the electric field crowding at the interface with the gate electrode 142.

The interface 142f between the insulating film 132 and the gate electrode 142 is located on the semiconductor layer 113-side of the pn junction interface 111f between the semiconductor layer 111 and the semiconductor layer 112. This configuration reduces the depth of the trench 122 and thereby gains the thickness of the semiconductor layer 111. This results in enhancing the breakdown voltage of the semiconductor device 100.

The insulating film 132 is formed from the side face film portion 131s over the bottom face film portion 131b. The insulating film 132 can be readily provided by the film formation technique having anisotropy.

### B. Second Embodiment

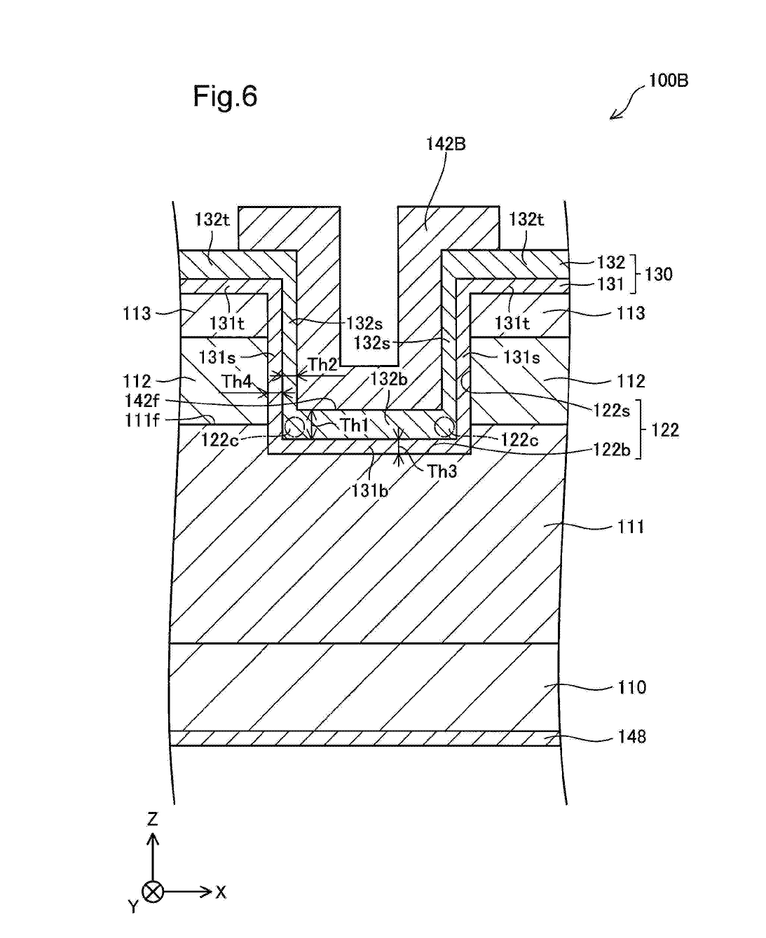

FIG. 6 is a sectional view schematically illustrating the configuration of a semiconductor device 100B according to a second embodiment. The semiconductor device 100B has configuration similar to that of the semiconductor device 100 of the first embodiment, except that gate electrodes 142B are provided in place of the gate electrodes 142. The gate electrode 142B of the semiconductor device 100B is similar to the gate electrode 142 of the first embodiment, except that the gate electrode 142B is formed along the side face 122s and the bottom face 122b of the trench 122.

According to the second embodiment, the thickness Th1 of the insulating film 132 formed on the insulating film 131 is greater than the thickness Th2, like the first embodiment. This configuration enables the insulating film 132 located in the corner portions 122c to effectively reduce the electric field crowding at an interface of the gate electrode 142B. This configuration can thus effectively reduce the electric field crowding in the trench MIS structure formed in the trench 122.

### C. Third Embodiment

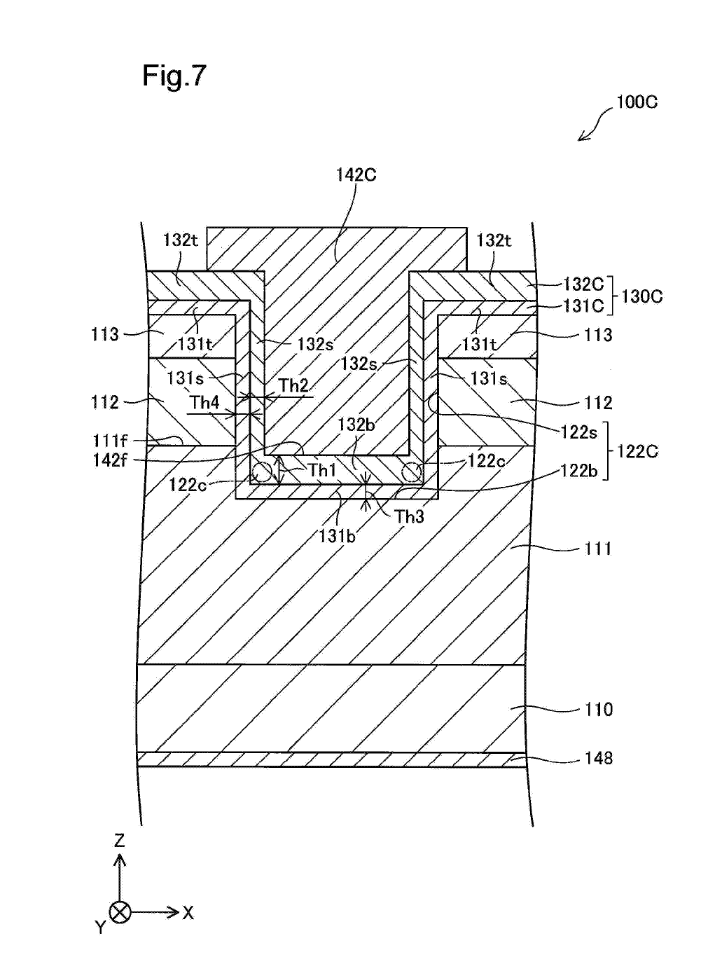

FIG. 7 is a sectional view schematically illustrating the configuration of a semiconductor device 100C according to a third embodiment. The semiconductor device 100C has configuration similar to that of the semiconductor device 100 of the first embodiment, except that a trench 122C formed has a greater depth than that of the trench 122 of the first embodiment, an insulating film 130C is provided in place of the insulating film 130, and gate electrodes 142C are provided in place of the gate electrodes 142.

The trench 122C of the semiconductor device 100C is similar to the trench 122 of the first embodiment, except that the trench 122C is recessed into the semiconductor layer 111 to the greater depth than the trench 122.

The insulating film 130C of the semiconductor device 100C includes an insulating film 131C and an insulating film 132C according to the shape of the trench 122C. The insulating film 131C of the insulating film 130C is similar to the insulating film 131 of the first embodiment, except that the insulating film 131C is formed according to the shape of the trench 122C. The insulating film 132C of the insulating film 130C is similar to the insulating film 132 of the first embodiment, except that the insulating film 132C is formed according to the shape of the trench 122C.

The gate electrode 142C of the semiconductor device 100C is similar to the gate electrode 142 of the first embodiment, except that the gate electrode 142C is formed according to the shape of the trench 122C. According to this embodiment, an interface 142f between the insulating film 132C and the gate electrode 142C is located on the substrate 110-side (−Z-axis direction side) of the pn junction interface 111f between the semiconductor layer 111 and the semiconductor layer 112. This configuration further reduces the on resistance, compared with the first embodiment.

According to the third embodiment described above, the thickness Th1 of the insulating film 132C formed on the insulating film 131C is greater than the thickness Th2, like the first embodiment. This configuration enables the insulating film 132C located in the corner portions 122c to effectively reduce the electric field crowding at the interface of the gate electrode 142C. This configuration can thus effectively reduce the electric field crowding in the trench MIS structure formed in the trench 122C.

### D. Fourth Embodiment

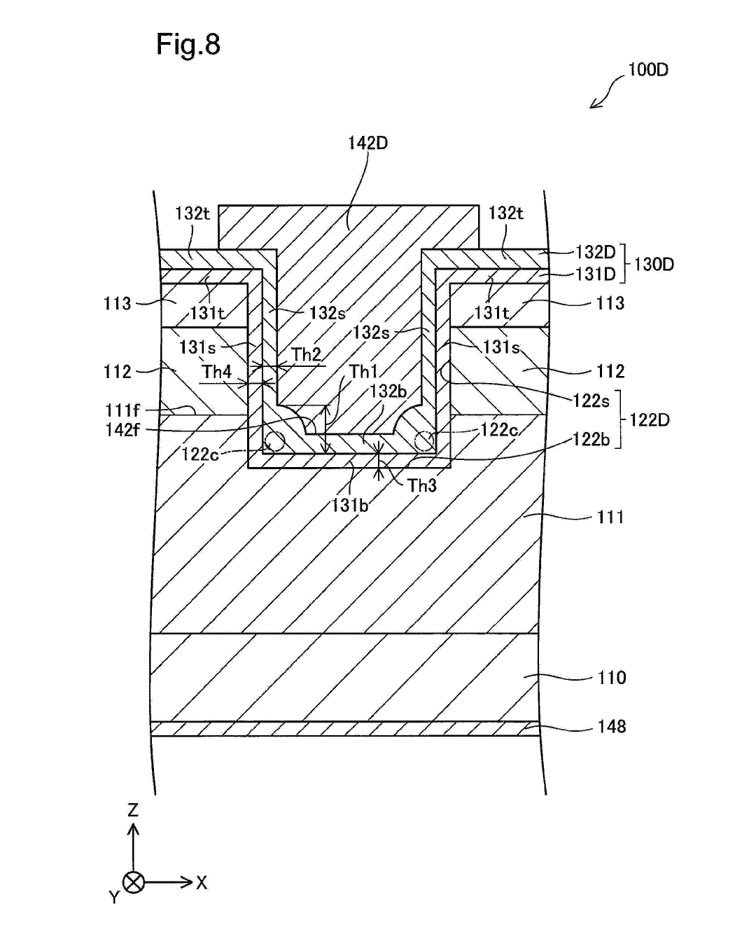

FIG. 8 is a sectional view schematically illustrating the configuration of a semiconductor device 100D according to a fourth embodiment. The semiconductor device 100D has configuration similar to that of the semiconductor device 100 of the first embodiment, except that a trench 122D formed has a greater depth than that of the trench 122 of the first embodiment, an insulating film 130D is provided in place of the insulating film 130, and gate electrodes 142D are provided in place of the gate electrodes 142.

The trench 122D of the semiconductor device 100D is similar to the trench 122 of the first embodiment, except that the trench 122D is recessed into the semiconductor layer 111 to the greater depth than the trench 122.

The insulating film 130D of the semiconductor device 100D includes an insulating film 131D and an insulating film 132D according to the shape of the trench 122D. The insulating film 131D of the insulating film 130D is similar to the insulating film 131 of the first embodiment, except that the insulating film 131D is formed according to the shape of the trench 122D. The insulating film 132D of the insulating film 130D is similar to the insulating film 132 of the first embodiment, except that the insulating film 132D is formed partly thicker in corner portions 122c. According to this embodiment, the insulating film 132D has a bottom face film portion 132b that is partly thicker in the corner portions 122c.

The gate electrode 142D of the semiconductor device 100D is similar to the gate electrode 142 of the first embodiment, except that the gate electrode 142D is formed according to the shape of the trench 122D. According to this embodiment, an interface 142f between the insulating film 132D and the gate electrode 142D is located on the substrate 110-side (−Z-axis direction side) of the pn junction interface 111f between the semiconductor layer 111 and the semiconductor layer 112. This configuration further reduces the on resistance, compared with the first embodiment.

According to the fourth embodiment described above, the thickness Th1 of the insulating film 132D formed on the insulating film 131D is greater than the thickness Th2, like the first embodiment. This configuration enables the insulating film 132D located in the corner portions 122c to effectively reduce the electric field crowding at the interface of the gate electrode 142D. This configuration can thus effectively reduce the electric field crowding in the trench MIS structure formed in the trench 122D. Additionally, the insulating film 132D is formed to be partly thicker in the corner portions 122c. This configuration reduces the amount of the insulating material required for the insulating film 132D, compared with the first embodiment.

### E. Fifth Embodiment

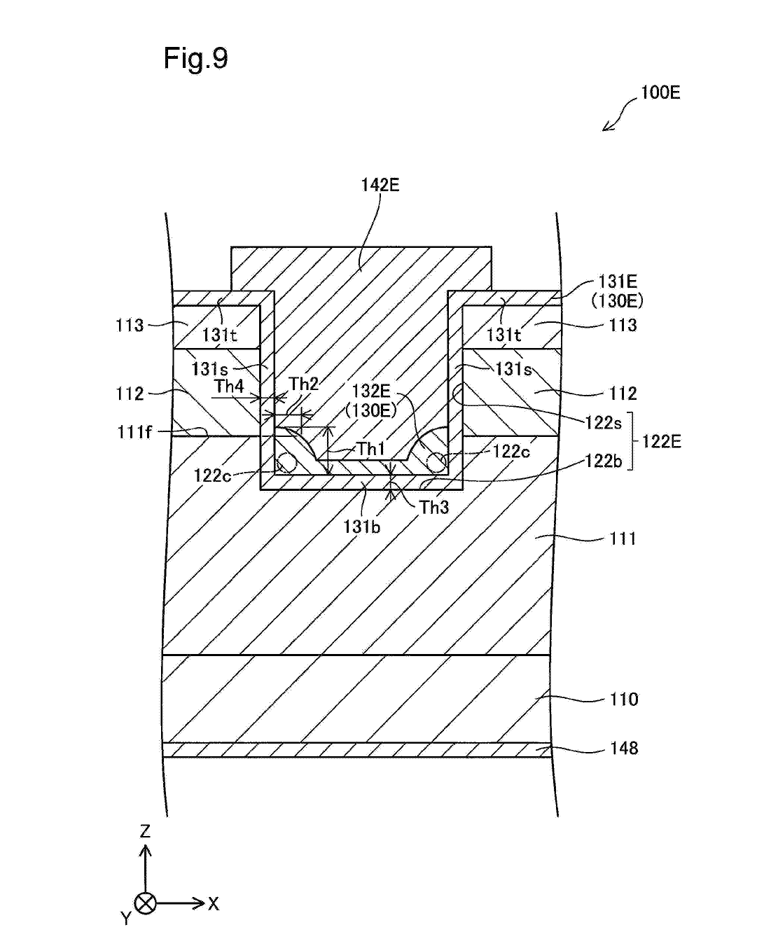

FIG. 9 is a sectional view schematically illustrating the configuration of a semiconductor device 100E according to a fifth embodiment. The semiconductor device 100E has configuration similar to that of the semiconductor device 100 of the first embodiment, except that a trench 122E formed has a greater depth than that of the trench 122 of the first embodiment, an insulating film 130E is provided in place of the insulating film 130, and gate electrodes 142E are provided in place of the gate electrodes 142.

The trench 122E of the semiconductor device 100E is similar to the trench 122 of the first embodiment, except that the trench 122E is recessed into the semiconductor layer 111 to the greater depth than the trench 122.

The insulating film 130E of the semiconductor device 100E includes an insulating film 131E and an insulating film 132E according to the shape of the trench 122E. The insulating film 131E of the insulating film 130E is similar to the insulating film 131 of the first embodiment, except that the insulating film 131E is formed according to the shape of the trench 122E. The insulating film 132E of the insulating film 130E is similar to the insulating film 132 of the first embodiment, except that the insulating film 132E excludes the side face film portion 132s and the upper film portion 132t and is formed partly thicker in corner portions 122c. According to this embodiment, the insulating film 132E is formed over the entire bottom face film portion 131b of the insulating film 131E and is formed thicker in the corner portions 122c.

The gate electrode 142E of the semiconductor device 100E is similar to the gate electrode 142 of the first embodiment, except that the gate electrode 142E is formed according to the shape of the trench 122E.

According to the fifth embodiment described above, the thickness Th1 of the insulating film 132E formed on the insulating film 131E is greater than the thickness Th2, like the first embodiment. This configuration enables the insulating film 132E located in the corner portions 122c to effectively reduce the electric field crowding at an interface of the gate electrode 142E. This configuration can thus effectively reduce the electric field crowding in the trench MIS structure formed in the trench 122E. Additionally, the insulating film 132E is formed to be partly thicker in the corner portions 122c. This configuration reduces the amount of the insulating material required for the insulating film 132E, compared with the first embodiment.

### F. Sixth Embodiment

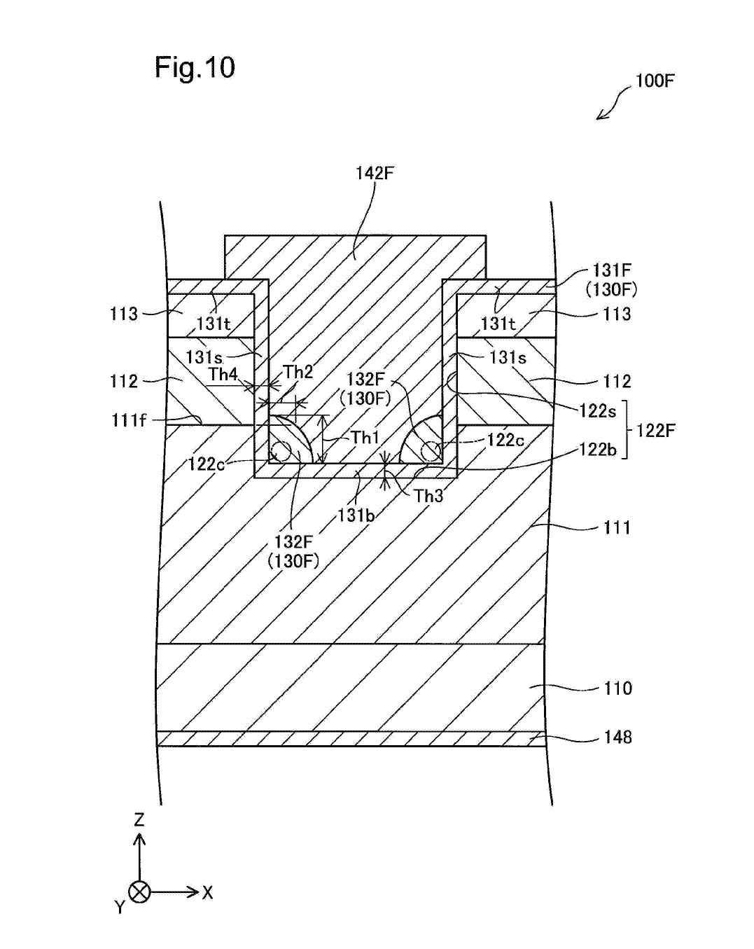

FIG. 10 is a sectional view schematically illustrating the configuration of a semiconductor device 100F according to a sixth embodiment. The semiconductor device 100F has configuration similar to that of the semiconductor device 100 of the first embodiment, except that a trench 122F formed has a greater depth than that of the trench 122 of the first embodiment, an insulating film 130F is provided in place of the insulating film 130, and gate electrodes 142F are provided in place of the gate electrodes 142.

The trench 122F of the semiconductor device 100F is similar to the trench 122 of the first embodiment, except that the trench 122F is recessed into the semiconductor layer 111 to the greater depth than the trench 122.

The insulating film 130F of the semiconductor device 100F includes an insulating film 131F and an insulator 132F according to the shape of the trench 122F. The insulating film 131F of the insulating film 130F is similar to the insulating film 131 of the first embodiment, except that the insulating film 131F is formed according to the shape of the trench 122F. The insulator 132F of the insulating film 130F is similar to the insulating film 132 of the first embodiment, except that the insulator 132F is formed partly in corner portions 122c.

The gate electrode 142F of the semiconductor device 100F is similar to the gate electrode 142 of the first embodiment, except that the gate electrode 142F is formed according to the shape of the trench 122F.

According to the sixth embodiment described above, the thickness Th1 of the insulator 132F formed on the insulating film 131F is greater than the thickness Th2, like the first embodiment. This configuration enables the insulator 132F located in the corner portions 122c to effectively reduce the electric field crowding at an interface of the gate electrode 142F. This configuration can thus effectively reduce the electric field crowding in the trench MIS structure formed in the trench 122F. Additionally, the insulator 132F is partly formed in the corner portions 122c. This configuration reduces the amount of the insulating material required for the insulator 132F, compared with the first embodiment.

### G. Other Embodiments

The invention is not limited to any of the embodiments, the examples and the modifications described above but may be implemented by a diversity of other configurations without departing from the scope of the invention. For example, the technical features of any of the embodiments, the examples and modifications corresponding to the technical features of each of the aspects described in Summary may be replaced or combined appropriately, in order to solve part or all of the problems described above or in order to achieve part or all of the advantageous effects described above. Any of the technical features may be omitted appropriately unless the technical feature is described as essential herein.

The semiconductor device which the present invention is applied to is not limited to the vertical trench MOSFET described in the above embodiments but may be any semiconductor device having the trench MIS structure, for example, an insulated gate bipolar transistor (IGBT) or an MESFET (metal-semiconductor field effect transistor). The trench MIS structure of the invention may be applied as the terminating structure.

In the embodiments described above, the material of the substrate is not limited to gallium nitride (GaN) but may be any of silicon (Si), sapphire (Al₂O₃) and silicon carbide (SiC). In the embodiments described above, the material of each semiconductor layer is not limited to gallium nitride (GaN) but may be any of silicon (Si), silicon carbide (SiC), nitride semiconductors, diamond, gallium oxide (Ga₂O₃), gallium arsenide (GaAs) and indium phosphide (InP). In the semiconductor device which the present invention is applied to, the material of the substrate is preferably a material having a larger band gap than silicon (Si), and gallium nitride (GaN), silicon carbide (SiC), diamond and gallium oxide (Ga₂O₃) are especially preferable. This effectively reduces the electric field crowding in the trench MIS structure in a semiconductor device that is required to have the higher breakdown voltage than the semiconductor device using silicon (Si).

In the embodiments described above, the donor element contained in the n-type semiconductor layer is not limited to silicon (Si) but may be germanium (Ge) or oxygen (O).

In the embodiments described above, the acceptor element contained in the p-type semiconductor layer is not limited to magnesium (Mg) but may be zinc (Zn) or carbon (C).

In the embodiments described above, the first insulating material may be any insulating material that reduces the interface state density at interfaces with the semiconductor layers 111, 112 and 113 and form good interfaces. For example, the first insulating material may be silicon dioxide (SiO₂), silicon oxynitride (SiON), aluminum oxide (Al₂O₃), aluminum oxynitride (AlON) or gallium oxide (Ga₂O₃).

In the embodiments described above, the second insulating material may be any insulating material that has the higher relative permittivity than that of the first insulating material. The second insulating material may be any of oxides and oxynitrides containing at least one element selected from the group consisting of aluminum (Al), hafnium (Hf), titanium (Ti), zirconium (Zr), tantalum (Ta) and lanthanum (La).

The combination of the first insulating material and the second insulating material may be any of the following: (first insulating material)/(second insulating material) silicon dioxide SiO₂)/aluminum oxide (Al₂O₃) silicon dioxide SiO₂)/gallium oxide (Ga₂O₃) silicon dioxide SiO₂)/hafnium oxide (HfO₂) silicon dioxide SiO₂)/hafnium silicon oxynitride (HfSiON) silicon dioxide SiO₂)/zirconium oxide (ZrO₂) silicon dioxide SiO₂)/zirconium oxynitride (ZrON) gallium oxide (Ga₂O₃)/hafnium oxide (HfO₂) gallium oxide (Ga₂O₃)/hafnium silicon oxynitride (HfSiON) gallium oxide (Ga₂O₃)/zirconium oxide (ZrO₂) gallium oxide (Ga₂O₃)/zirconium oxynitride (ZrON) aluminum oxide (Al₂O₃)/hafnium oxide (HfO₂) aluminum oxide (Al₂O₃)/hafnium silicon oxynitride (HfSiON) aluminum oxide (Al₂O₃)/zirconium oxide (ZrO₂) aluminum oxide (Al₂O₃)/zirconium oxynitride (ZrON)

In the embodiments described above, the first insulator mainly made of the first insulating material may have a two-layered or multi-layered structure. The second insulator mainly made of the second insulating material may have a two-layered or multi-layered structure. The material of each electrode is not limited to the material described in the above embodiments but may be any other suitable material.

What is claimed is:

1. A semiconductor device, comprising:
a first semiconductor layer that is configured to have one characteristic out of n-type and p-type characteristics;
a second semiconductor layer that is configured to have the other characteristic out of the n-type and p-type characteristics that is different from the one characteristic, and is stacked on the first semiconductor layer;
a third semiconductor layer that is configured to have the one characteristic and is stacked on the second semiconductor layer;
a trench that is formed from the third semiconductor layer to penetrate through the second semiconductor layer and to be recessed into the first semiconductor layer and is configured to include a side face and a bottom face;
a first insulator that is mainly made of a first insulating material, is provided as a film formed from the side face over the bottom face, and is configured to include a side face film portion formed on the side face and a bottom face film portion formed on the bottom face;
a second insulator that is mainly made of a second insulating material having a higher relative permittivity than relative permittivity of the first insulating material and is formed in at least a corner portion of an area defined by the side face film portion and the bottom face film portion; and
an electrode that is formed inside of the trench via the first insulator and the second insulator, wherein
a thickness Th1 of the second insulator in an area located in the corner portion is greater than a thickness Th2 of the second insulator in an area where the side face film portion is placed between the second insulator and the second semiconductor layer, wherein
the thickness Th1 denotes a thickness relative to a surface of the bottom face film portion and
the thickness Th2 denotes a thickness relative to a surface of the side face film portion.

2. The semiconductor device according to claim 1, wherein
the thickness Th1 is greater than a thickness of the first insulator.

3. The semiconductor device according to claim 1, wherein
the bottom face film portion has a thickness that is equal to or greater than a thickness of the side face film portion.

4. The semiconductor device according to claim 1, wherein
the thickness Th1 is equal to or greater than twice a thickness of the bottom face film portion.

5. The semiconductor device according to claim 1, wherein
an interface between the second insulator and the electrode is located on a third semiconductor layer side of an interface between the first semiconductor layer and the second semiconductor layer.

6. The semiconductor device according to claim 1, wherein
the second insulator is a film formed from the side face film portion over the bottom face film portion.

7. The semiconductor device according to claim 1, wherein
the second insulator includes
a film portion that is formed on the side face film portion to have the thickness Th2 and
a film portion that is formed on the bottom face film portion to have the thickness Th1.

8. The semiconductor device according to claim 1, wherein
the second insulator is formed partly thicker in the corner portion.

9. The semiconductor device according to claim 1, wherein
the second insulator is partly formed in the corner portion.

10. The semiconductor device according to claim 1, wherein
the first insulating material includes at least one selected from the group consisting of silicon dioxide (SiO₂), silicon oxynitride (SiON), aluminum oxide (Al₂O₃), aluminum oxynitride (AlON) and gallium oxide (Ga₂O₃).

11. The semiconductor device according to claim 1, wherein
the second insulating material includes at least one of oxides and oxynitrides containing at least one element selected from the group consisting of aluminum (Al), hafnium (Hf), titanium (Ti), zirconium (Zr), tantalum (Ta) and lanthanum (La).

12. The semiconductor device according to claim 1, wherein
at least one semiconductor layer among the first semiconductor layer, the second semiconductor layer and the third semiconductor layer is mainly made of a semiconductor that has a greater band gap than a band gap of silicon (Si).

13. The semiconductor device according to claim 1, wherein
at least one semiconductor layer among the first semiconductor layer, the second semiconductor layer and the third semiconductor layer is mainly made of at least one selected from the group consisting of silicon carbide (SiC), a nitride semiconductor, diamond and gallium oxide (Ga₂O₃).

14. A power converter, comprising
the semiconductor device according to claim 1.

15. A method of manufacturing a semiconductor device, the method comprising:
forming a first semiconductor layer having one characteristic out of n-type and p-type characteristics, on a substrate;
stacking a second semiconductor layer having the other characteristic out of the n-type and p-type characteristics that is different from the one characteristic, on the first semiconductor layer;
stacking a third semiconductor layer having the one characteristic, on the second semiconductor layer;
forming a trench that includes a side face and a bottom face by etching from the third semiconductor layer through the second semiconductor layer to the first semiconductor layer;
forming a first insulator as a film formed from the side face over the bottom face by using a first insulating material, such that the first insulator includes a side face film portion formed on the side face and a bottom face film portion formed on the bottom face;
forming a second insulator in at least a corner portion of an area defined by the side face film portion and the bottom face film portion by using a second insulating material having a higher relatively permittivity than relative permittivity of the first insulating material; and
forming an electrode inside of the trench that the first insulator and the second insulator are formed in, wherein
the forming the second insulator comprises making a thickness Th1 of the second insulator in an area located in the corner portion greater than a thickness Th2 of the second insulator in an area where the side face film portion is placed between the second insulator and the second semiconductor layer, wherein
the thickness Th1 denotes a thickness relative to a surface of the bottom face film portion and
the thickness Th2 denotes a thickness relative to a surface of the side face film portion.

16. The method of manufacturing the semiconductor device according to claim 15,
wherein the forming the second insulator comprises forming the second insulator by sputtering.

17. The method of manufacturing the semiconductor device according to claim 16,
wherein the sputtering is electron cyclotron resonance sputtering.

18. The method of manufacturing the semiconductor device according to claim 17, the method further comprising
adjusting thickness of the second insulator by controlling an angle between a radiation direction of target particles and the substrate.
